(19) United States
(12) Patent Application Publication
(10) Pub. No.: US 2013/0048336 A1
(43) Pub. Date: Feb. 28, 2013

(54) POLYMERIC COATED BUSBAR TAPE FOR PHOTOVOLTAIC SYSTEMS

(71) Applicant: Ranjit MALIK, York, PA (US)

(72) Inventor: Ranjit MALIK, York, PA (US)

(73) Assignee: ADHESIVES RESEARCH, INC., Glen Rock, PA (US)

(21) Appl. No.: 13/589,287

(22) Filed: Aug. 20, 2012

Related U.S. Application Data
(60) Provisional application No. 61/525,941, filed on Aug. 22, 2011.

(51) Int. Cl. H01B 7/28; B32B 15/08; C09J 7/02; H01L 31/18; H01L 51/48

(52) U.S. Cl. 174/68.2; 438/97; 438/82; 428/344; 428/354; 428/335; 428/336; 257/E51.012; 257/E31.004

(57) ABSTRACT

A tape is disclosed. The tape includes a metallic foil, an adhesive layer laminated on one surface of the metallic foil and a protective polymeric coating laminated on an opposing second surface of the metallic foil. The protective coating comprises an anti-corrosion agent. The protective coating shields the metallic foil from corrosion and other drawbacks that can occur by environmental exposure. The tape readily can be employed as a busbar tape in photovoltaic cells to provide a cost-effective substitute for the tin-coated copper currently used there.

### CROSS-REFERENCE TO RELATED APPLICATIONS

This application claims priority to U.S. Application No. 61/525,941 filed Aug. 22, 2011, which is hereby incorporated by reference in its entirety.

### FIELD

The present disclosure is directed to electrically conductive components and more particularly to a polymeric coated busbar adhesive tape for use in photovoltaic systems and other various applications.

### BACKGROUND

The high production cost of photovoltaic cells and modules has delayed widespread adoption of such systems for electrical generation. Furthermore, high reliability of electrical interconnects within a solar cell is important to maintaining the long expected functional lifetime of such a device; most solar panels are rated to perform for 20-30 years at high efficiencies.

Busbars, a metal strip or plate used in electrical distribution to transfer power from one system to another, are used in photovoltaic systems for various functions. For example, busbars in photovoltaic systems are used to collect the electric charge from the surface of the solar cell, to electrically string individual solar cells together in order to form modules, and to transfer electrical power from the modules for subsequent external distribution.

Historically, printed lines of silver paste have been used as busbars in photovoltaic systems. However, the silver paste requires a high temperature firing step that is not compatible with more newly developed photovoltaic technologies, such as thin film and organic dye based cells.

More recently, conductive tapes have found increasing use as busbars in photovoltaic systems. In such situations, the conductive tape is typically a metal foil coated with an adhesive. The conventional metal foil used to manufacture busbars based on conductive tapes is a tri-layer construction consisting of copper foil with a cladding of tin on both surfaces. The tin cladding is used because the copper would otherwise have a tendency to corrode or tarnish over a period of time that, in turn, could compromise the intended longevity of the photovoltaic systems. The tin cladding process of the copper, however, makes the conductive tape very expensive, contributing to the high component cost that decreases the attractiveness of implementing solar technology.

These and other drawbacks are present in current photovoltaic systems.

### SUMMARY

According to exemplary embodiments, busbars for photovoltaic systems are provided that provide a commercially attractive alternative to expensive tin cladding of copper foil. The inventor has discovered that copper foil can be coated with formulated polymeric coatings that provide sufficient resistance against corrosion of the underlying copper while under electrical load. In accordance with exemplary embodiments, the coated foil can be used to make conductive tapes that can be used for busbar applications in photovoltaic and other electronic systems. The inventor also discovered that polymeric coatings with both sufficient flex resistance and adhesion to copper were successful. Moreover, polymeric coatings that do not form microcracks and do not delaminate from copper when flexed or die cut are suitable in this invention. The polymeric coating incorporates an anti-corrosion agent. Exemplary embodiments thus provide for a substantial cost savings over tin clad copper foil without adversely impacting performance.

According to one embodiment a coated metallic foil tape comprises a metallic foil, an adhesive layer laminated on one surface of the metallic foil, and a protective polymeric coating laminated on an opposing second surface of the metallic foil. The protective coating includes an anti-corrosion agent.

In one embodiment, a coated metallic foil busbar tape comprises a metallic foil of copper or copper alloy, an adhesive layer laminated on one surface of the metallic foil, the adhesive layer containing an adhesive and a plurality of conductive particles present at about 25% to about 160% by weight solids of the adhesive; and a protective polymeric coating laminated on an opposing second surface of the metallic foil. The protective coating has a glass transition temperature (T_{g}) less than 30° C. and includes an anti-corrosion agent selected from the group consisting of alkylammonium salt solutions, indazole, 2-mercaptobenzotriazole, benzimidazole, 5-methyl-1H-benzotriazole, 1H-benzotriazole, 5-chlorobenzotriazole, 5-amino-2-mercapto-1,3,4-thiadiazole, 2-mercaptobenzimidazole, sterically hindered phenolic antioxidants, chromate, and combinations thereof. The protective polymeric layer optionally includes a plasticizer and optionally includes a tackifier.

According to another embodiment, a method of constructing a photovoltaic device comprises providing a photovoltaic cell and applying the coated metallic foil tapes described herein to make an electrical interconnection within the photovoltaic cell.

An advantage of exemplary embodiments is that a busbar tape is provided that does not require more time consuming and expensive cladding operations to protect the copper.

Another advantage is that exemplary embodiments can be used in photovoltaic systems to withstand harsh environmental conditions.

Yet another advantage is that exemplary embodiments provide a busbar tape that can be used to more cost efficiently provide photovoltaic systems and thereby increase the attractiveness of implementing solar technology.

These and other advantages will be apparent from the following more detailed description of exemplary embodiments.

### BRIEF DESCRIPTION OF THE DRAWINGS

FIG. 1 schematically illustrates a side view of a polymeric coated metallic foil busbar tape in accordance with an exemplary embodiment.

FIG. 2 schematically illustrates a photovoltaic system that employs a polymeric coated metallic foil busbar tape in accordance with exemplary embodiments.

### DETAILD DESCRIPTION OF EXEMPLARY EMBODIMENTS

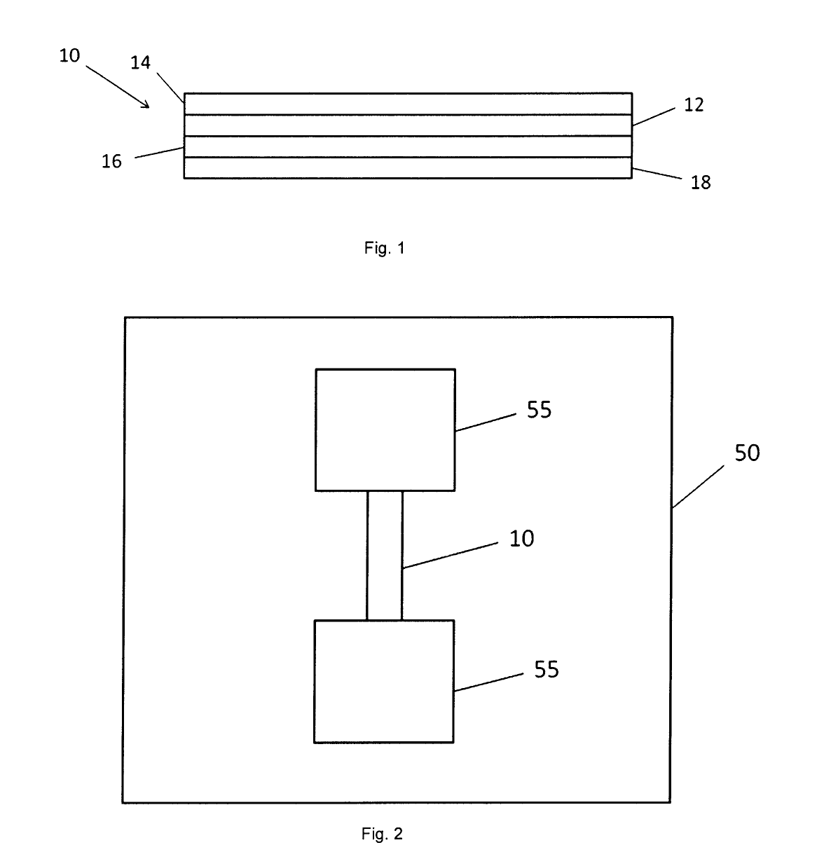

According to exemplary embodiments and with reference to FIG. 1, a polymeric coated metallic foil busbar tape 10 is provided for use in a photovoltaic or other suitable system that provides a commercially attractive alternative to expensive tin cladding of copper foil. The busbar tape 10 includes a conductive metallic foil 12. A formulated protective polymeric coating 14 that employs an anti-corrosion agent is laminated to at least one side of the metallic foil 12. An adhesive layer 16 is laminated to an opposite surface of the metallic foil 12 to form the busbar tape 10; a release layer 18 is optionally applied over the adhesive layer 16 to cover it and prevent unintended application prior to the tape's use in a photovoltaic or other system with which the busbar tape 10 will be employed.

The metallic foil 12 used in accordance with exemplary embodiments is typically, but not limited to, electrodeposited copper foil or wrought copper foil. The reference to copper foil includes foils of both pure copper and copper alloys, in either case which may advantageously be free of tin or other expensive cladding when used in accordance with exemplary embodiments. Although primarily discussed herein with respect to copper foil, other metallic foils may also be used in accordance with exemplary embodiments including aluminum, tungsten, tin, and steel, as well as alloys containing these materials. The foil 12 may be a solid foil, which is typically smooth, but may be embossed or have other surface features. Alternatively, the foil 12 may be a mesh construction. The foil 12 may be of any suitable thickness for use as a conductive tape, typically, but not necessarily, between 10 and 75 microns.

The protective polymeric coating 14 can be comprised of any polymeric material that exhibits sufficient adhesion when applied to the copper foil 12 and that is sufficiently flexible at ambient conditions to resist the formation of microcracks and that maintains its adhesion and resists flaking from the copper foil 12 after exposure to heat and humidity. Suitable polymeric materials for use in the protective polymeric coating 14 include polyacrylates, polyurethanes, block copolymers, polyisobutylene, silicone, polyester, epoxy, and combinations thereof, all by way of example only. Exemplary compounds for use in the polymeric coating 14 include those commercially available from Evonik as Dynapol L208 (a polyester resin), Dynapol LH823-01 (a polyester resin), Vesticoat UB790 (a polyester polyurethane block copolymer), and Oppanol B (a polyisobutylene resin available from BASF).

The glass transition temperature of the protective polymeric coating 14 should be in a region that provides for a flexible coating at ambient temperature, typically having a T_{g} less than about 30° C. In some embodiments, a plasticizer may be added to enhance the flexibility of the base polymer selected for use in the protective polymeric coating 14, such as in situations where the T_{g} of that material is in excess of 30° C., when that coating is applied to the copper foil 12. The use of materials having a T_{g} less than 30° C. provides flexibility in the polymeric coating 14 that is resistant to microcrack formation. The microcracks can serve as a point of entry for moisture or oxygen, particularly under harsh environmental conditions, that can become propagation points for delamination, corrosion or other failure.

In other embodiments, a tackifier may be employed to ensure sufficient anchorage of the polymeric coating 14 to the foil substrate 12. Exemplary tackifiers include hydrocarbon resins such as that commercially available from Arakawa as Arkon P140. Other tackifier compounds are known in the art and any may be employed, although tackifier selection should not result in adversely affecting the coating's flexibility that aids in resisting microcrack formation as previously described. In certain embodiments, in lieu of a tackifier, a primer may be applied to the foil 12 prior to the polymeric coating 14 to achieve a suitable level of anchorage.

In some embodiments, a plasticizer may be employed to increase flexibility by lowering the glass transition temperature in combination with the addition of a tackifier to enhance anchorage of the protective polymeric coating 14 to the foil 12.

Additionally, the polymeric coating 14 may optionally be crosslinked according to any crosslinking chemistry known to those skilled in the art. It will be appreciated, however, that the use and/or type of cross-linking may depend in part on compatibility of a particular cross-linking chemistry with the photovoltaic fabrication process of the cell in which the busbar is being employed. That fabrication process may, for example, place limitations on exposure to heat and/or UV radiation used to initiate any cross-linking reaction.

The polymeric coating 14 in accordance with exemplary embodiments further comprises an anti-corrosion agent. This additive aids in protecting the underlying copper foil from oxidation and tarnish, as well as other chemical reactions that have a corrosive effect on the surface and/or bulk of the copper foil 12. The anti-corrosion agent is typically present at about 0.1 to about 5 percent by weight of the total dry polymeric coating (i.e., excluding solvent content). Suitable anti-corrosion agents include, but are not limited to alkylammonium salt solutions, such as Halox 630 and Halox 650 (both available from Halox), Tarniban 260 (available from Technic Inc.), indazole, 2-mercaptobenzotriazole, benzimidazole, 5-methyl-1H-benzotriazole, 1H-benzotriazole, 5-chlorobenzotriazole, 5-amino-2-mercapto-1,3,4-thiadiazole, 2-mercaptobenzimidazole, sterically hindered phenolic antioxidants, such as Irganox 1010 (available from Ciba), chromate, and combinations thereof.

The polymeric coating 14 may be manufactured as a solvent-based coating using a suitable solvent that dissolves the polymeric material. The solution can then be applied as a thin film overlying one side of the copper foil 12, followed by driving off the solvent, typically by drying at elevated temperatures, which can be accomplished more easily and less expensively than tin or other protective claddings but which still provides a suitably protective barrier from water and oxygen with respect to the underlying copper foil 12. The polymeric coating 14, after drying, typically has a thickness in the range of about 1 to about 40 microns, more typically in the range of about 12.5 to about 25 microns.

The use of a coated foil in a conductive tape format can aid to simplify the assembly process of a photovoltaic cell and other systems in which the busbars will be used. That is, the now-coated metal foil 12 may be provided in the form of a conductive tape for use in cell manufacturing. Conductive tapes typically allow for low temperature application, provide a well defined bondline, and allow efficient and rapid application.

The busbar tape 10 may be provided by coating the metal foil 12 with an adhesive layer 16 on the side of the metal foil 12 opposite from the protective polymeric coating 14. A release layer 18 may be applied to the adhesive layer 16 to protect it prior to the tape's intended application. The adhesive layer 16 may be a pressure sensitive adhesive and preferably is a conductive pressure sensitive adhesive composition. Any suitable conductive adhesive composition may be employed, which may include a pressure sensitive adhesive matrix filled with electrically conductive particles. The conductive particles may be present at about 25% by weight to about 160% by weight solids of the adhesive (i.e. excluding the mass of any optional solvents). Preferably the conductive particles may be present at about 50% by weight to about 140% by weight of solids of the adhesive. Most preferably the conductive particle may be present at about 60% by weight to about 120% by weight of solids of the adhesive. Conductive particles include metals such as silver, gold, nickel, and copper, as well as carbon black, carbon fiber, metalized carbon fiber, silver coated glass beads, silver coated glass flakes/fibers, and silver coated nickel particles, all by way of example.

Furthermore, the pressure sensitive adhesive may also include an anti-corrosion agent, present in about the same amounts and of the same types as described with respect to the polymeric coating 14. Thus, both sides of the bare copper foil 12 may be covered by a material containing an anti-corrosion agent. While the adhesive side of the foil 12 may have less exposure to conditions that are likely to lead to corrosion as a result of that side being adhered to the cell, it may nevertheless be advantageous to incorporate the anti-corrosion agent into the adhesive as well. It will be appreciated that the amount and type of anti-corrosion agent does not need to be identical in both the adhesive and polymeric coating applied to a particular foil. In some embodiments, the foil 12 may optionally be coated by the polymeric coating 14 on both sides, with the adhesive layer 16 applied directly overlying one of the polymeric coating layers 14 (or both sides in the case of a double-sided tape).

In forming a conductive tape in accordance with exemplary embodiments, the polymeric coating and the adhesive may be applied to the metal foil in any order or simultaneously. In some cases, the particular order may depend in part on the cure profile of the adhesive and/or any cross-linking agents employed in the polymeric coating.

Polymeric coated metallic busbar tapes 10 in accordance with exemplary embodiments may be provided for use in various types of solar and other photovoltaic cells 50, as schematically illustrated in FIG. 2, in which an electrical interconnection is achieved between two electrodes 55 connected by the polymeric coated metallic busbar tape 10, which may be accomplished in accordance with conventional methods of making such interconnections. Exemplary types of photovoltaic cells 50 in which exemplary embodiments may be employed include crystalline silicon, polycrystalline silicon, inorganic thin film (e.g. CdTe, CIGS, etc.), and organic photovoltaic cells. Furthermore, the cells 50 may be rigid or flexible depending on their intended use. Examples of regions within a photovoltaic cell 50 where such busbars might be used include, but are not limited to, the charge collection grid, ribbon connections between cells, and electrodes for connection to external circuitry.

It will be appreciated that the type of photovoltaic cell 50 and its intended end use may have a bearing on the material selection for the cell's fabrication which may, in turn, have a bearing on the particular polymeric material, crosslinking agent, and/or anti-corrosion agent employed in the polymeric coating 14 and/or the adhesive layer 16.

### EXAMPLES

The invention is further described by way of the following examples, which are presented by way of illustration, not of limitation.

### Example 1

200 g of a polyester resin (Dynapol L208, commercially available from Evonik and having a reported glass transition temperature T_{g} of 65° C.) was mixed with 200 g of methyl ethyl ketone as a solvent. Then 5.6 gram of a cross-linking agent, Desmodur E28 (commercially available from Bayer), along with 4 gram of the corrosion inhibitor Irganox 1010 (commercially available from Ciba) and 5 gram of the corrosion inhibitor Halox 650 (commercially available from Halox) were all added to the above solution and dispersed thoroughly. The mixture was then coated on 17.5 micron thick copper foil and placed in an oven at 150° C. for 2 minutes to evaporate the solvent. The dry coating thickness was 12.5 microns. An electrically conductive pressure sensitive adhesive was laminated to the second side of the copper foil.

### Example 2

15 grams of a polyisobutylene (Oppanol B100, commercially available from BASF and having a reported glass transition temperature T_{g} of about −61° C.) was dissolved in a mixture of 16 grams heptane and 64.8 grams of toluene as the solvent. A separate solution of 0.9 grams of the corrosion inhibitor 1H-benzotriazole was prepared in 4.25 grams of acetone. Subsequently, the second solution was added to the first and mixed to form a homogeneous solution. Thereafter, 15 grams of the hydrocarbon resin Arkon P140, commercially available from Arakawa, was added to the mixture and mixed until it completely dissolved. The final mixture was coated on 35 micron thick wrought copper foil (grade 110) and placed in an oven at 120° C. for 4 minutes to evaporate the solvent. The dry coating thickness was 10 microns. An electrically conductive pressure sensitive adhesive was laminated to the second side of the copper foil.

### Example 3

7.5 grams of Oppanol B100 was dissolved in a mixture of 8 grams of heptane and 32.4 grams of toluene as the solvent. A separate solution of 0.26 grams of the corrosion inhibitor 5-methyl-1H-benzotriazole was prepared in 2.13 grams of acetone. Subsequently, the second solution was added to the first and mixed to form a homogeneous solution. Thereafter, 7.5 grams of Arkon P140 was added to the mixture and mixed until it completely dissolved. The final mixture was coated on 35 micron thick wrought copper foil (grade 110) and placed in an oven at 120° C. for 4 minutes to evaporate the solvent. The dry coating thickness was 10 microns. An electrically conductive pressure sensitive adhesive was laminated to the second side of the copper foil.

### Example 4

15 grams of Oppanol B100 was dissolved in a mixture of 16 grams heptane and 64.8 grams of toluene as the solvent. A separate solution of 0.9 grams of the corrosion inhibitor 5-methyl-1H-benzotriazole was prepared in 4.25 grams of acetone. Subsequently, the second solution was added to the first and mixed to form a homogeneous solution. Thereafter, 15 grams of the hydrocarbon resin Arkon P140, commercially available from Arakawa, was added to the mixture and mixed until it completely dissolved. The final mixture was coated on 17.5 micron thick electrodeposited copper foil and placed in an oven at 120° C. for 4 minutes to evaporate the solvent. The dry coating thickness was 25 microns. An electrically conductive pressure sensitive adhesive was laminated to the second side of the copper foil.

The coated copper foils thus produced were each then subjected to environmental conditioning at 80° C. and 80% relative humidity for 75 days. Uncoated copper foil was used as a control. The foil samples were visually inspected periodically for signs of corrosion. Appearance of corrosion underneath the coated area on the foil constituted failure. Time to failure was recorded.

Additionally, for the coated samples, the adhesion of the coating to the copper foil and the flexibility were evaluated prior to conditioning. To test the adhesion of the protective coating, a 2.54 cm wide strip of masking tape was applied on top of the coating and then removed in one brisk stroke. The tape and the foil surfaces were examined for failure. Poorly anchored coatings delaminate from the copper foil and transferred on to the tape which constitutes failure. The purpose of this test was to qualitatively evaluate the adhesion of the coating to the substrate. In another test, the flexibility of the coating was evaluated. The coated foil was folded 180° on itself. The fold was then examined under a microscope for formation of micro-cracks. Formation of cracks was a qualitative indication of a failed sample.

Test results are reflected in Table I.

TABLE I

| | Adhesion to | | |
|---|---|---|---|
| | Copper Foil at | | |
| | Ambient | Flexibility by | |
| Sample | Temperature | Bend Test | Time to Failure |
| Bare copper | N/A | N/A | 14 days (heavy |
| foil | | | discoloration) |
| Example 1 | Good | Failed | Failed after 35 days of |
| | | | exposure |
| Example 2 | Good | Did not crack | Did not fail in 75 days of |
| | | | exposure |
| Example 3 | Good | Did not crack | Did not fail in 75 days of |
| | | | exposure |
| Example 4 | Good | Did not crack | Did not fail in 75 days of |
| | | | exposure |

While all four examples showed good adhesion to the copper foil at ambient temperature, Example 1, which had a high Tg but contained no added plasticizer in this formulation, did not exhibit sufficient flexibility at ambient temperature. Example 1 also did not contain any added tackifier, but still exhibited an anti-corrosive effect two and half times that of the bare copper. It is believed that the anti-corrosive agent was effective in preventing corrosion, but that under the accelerated environmental testing, anchorage between the polymeric coating and the foil was insufficient, resulting in some delamination that allowed direct contact of moisture and/or oxygen with the foil.

Examples 2 through 4 all had a polymeric coating with a low T_{g} that exhibited excellent flexibility, even without added plasticizer. These examples, all of which included the presence of a tackifier, also exhibited excellent corrosion resistance of the underlying copper foil even under accelerated environmental testing reflecting excellent anchorage of the polymeric coating containing the anti-corrosive agents.

While the invention has been described with reference to particular embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

1. A coated metallic foil tape comprising:
a metallic foil,
an adhesive layer laminated on one surface of the metallic foil; and
a protective polymeric coating laminated on an opposing second surface of the metallic foil, wherein the protective coating comprises an anti-corrosion agent.

2. The coated metallic foil tape of claim 1, wherein the metallic foil comprises copper or copper alloy.

3. The coated metallic foil tape of claim 1, wherein the protective polymeric coating further comprises a tackifier.

4. The coated metallic foil tape of claim 1, wherein the protective polymeric coating further comprises a plasticizer.

5. The coated metallic foil tape of claim 1, wherein the protective polymeric coating has a glass transition temperature of less than 30° C.

6. The coated metallic foil tape of claim 1, wherein the adhesive layer comprises an adhesive containing a plurality of conductive particles.

7. The coated metallic foil tape of claim 6, wherein the conductive particles are present at about 25% by weigh to about 160% by weight solids of the adhesive.

8. The coated metallic foil tape of claim 1, wherein the adhesive layer comprises an anti-corrosion agent.

9. The coated metallic foil tape of claim 1, wherein the anti-corrosion agent is present at about 0.1 to about 5% by weight solids of the protective polymeric coating.

10. The coated metallic foil tape of claim 1, wherein the anti-corrosion agent is selected from the group consisting of alkylammonium salt solutions, indazole, 2-mercaptobenzotriazole, benzimidazole, 5-methyl-1H-benzotriazole, 1H-benzotriazole, 5-chlorobenzotriazole, 5-amino-2-mercapto-1,3,4-thiadiazole, 2-mercaptobenzimidazole, sterically hindered phenolic antioxidants, chromate, and combinations thereof

11. The coated metallic foil tape of claim 1, further comprising a second protective polymeric coating comprising an anti-corrosive agent intermediate the metallic foil and the adhesive layer.

12. The coated metallic foil tape of claim 1, wherein the protective polymer coating is selected from the group consisting of polyacrylates, polyurethanes, block copolymers, polyisobutylene, silicone, polyester, epoxy, and combinations thereof.

13. The coated metallic foil tape of claim 1, wherein the protective polymer coating has a thickness in the range of about 1 microns to about 40 microns.

14. The coated metallic foil tape of claim 1, wherein the protective polymer coating has a thickness in the range of about 12.5 microns to about 25 microns.

15. A coated metallic foil busbar tape comprising:
a metallic foil comprising copper or copper alloy,
an adhesive layer laminated on one surface of the metallic foil, the adhesive layer containing an adhesive and a plurality of conductive particles present at about 25% to about 160% by weight solids of the adhesive; and
a protective polymeric coating laminated on an opposing second surface of the metallic foil, wherein the protective coating has a glass transition temperature less than 30° C. and further comprises about 0.1% to about 5% by weight solids of an anti-corrosion agent selected from the group consisting of alkylammonium salt solutions, indazole, 2-mercaptobenzotriazole, benzimidazole, 5-methyl-1H-benzotriazole, 1H-benzotriazole, 5-chlorobenzotriazole, 5-amino-2-mercapto-1,3,4-thiadiazole, 2-mercaptobenzimidazole, sterically hindered phenolic antioxidants, chromate, and combinations thereof, optionally a plasticizer and optionally a tackifier.

16. The coated metallic foil busbar tape of claim 15, wherein the protective polymer coating has a thickness in the range of about 12.5 microns to about 25 microns.

17. The coated metallic foil busbar tape of claim 15, wherein the plurality of conductive particles are present at about 60% to about 120% by weight solids of the adhesive.

18. The coated metallic foil busbar tape of claim 15, wherein the protective polymeric coating comprises polyisobutylene and a tackifier.

19. A method of constructing a photovoltaic device comprising:
providing a photovoltaic cell;
applying the coated metallic foil tape of claim 1 to make an electrical interconnection within the photovoltaic cell.

20. The method of claim 19, wherein the photovoltaic cell is a crystalline silicon, polycrystalline silicon, inorganic thin film, or organic photovoltaic cell.
